(19) United States
(12) Patent Application Publication
(10) Pub. No.: US 2024/0306379 A1
(43) Pub. Date: Sep. 12, 2024

(54) SEMICONDUCTOR DEVICE

(71) Applicant: SAMSUNG ELECTRONICS CO., LTD., Suwon-si (KR)

(72) Inventors: CHAN-SIC YOON, Suwon-si (KR); Jongmin Kim, Suwon-si (KR); Kiseok Lee, Suwon-si (KR)

(21) Appl. No.: 18/369,248

(22) Filed: Sep. 18, 2023

(30) Foreign Application Priority Data
Mar. 10, 2023 (KR) 10-2023-0031682

(51) Int. Cl. H10B 12/00

(52) U.S. Cl. CPC H10B 12/50; H10B 12/482; H10B 12/485

(57) ABSTRACT

A semiconductor device including: a substrate that includes a cell region and a peripheral region, wherein the cell region includes a cell active pattern; a cell gate structure on the cell active pattern; a bit-line structure electrically connected to the cell active pattern; a peripheral gate structure on the peripheral region; a peripheral etch stop layer on the peripheral gate structure; and a cover dielectric layer on the peripheral etch stop layer, wherein the bit-line structure includes: a bit-line conductive layer; a bit-line dielectric layer on the bit-line conductive layer; a cell etch stop layer on the bit-line dielectric layer; and a bit-line capping layer on the cell etch stop layer, wherein the peripheral gate structure includes: a peripheral gate conductive layer; and a peripheral gate capping layer on the peripheral gate conductive layer.

### CROSS-REFERENCE TO RELATED APPLICATION

This U.S. nonprovisional patent application claims priority under 35 U.S.C. § 119 to Korean Patent Application No. 10-2023-0031682 filed on Mar. 10, 2023 in the Korean Intellectual Property Office, the disclosure of which is incorporated by reference herein in its entirety.

### TECHNICAL FIELD

The present inventive concept relates to a semiconductor device, and more particularly, to a semiconductor device where both a cell region and a peripheral region incorporate an etch stop layer.

### DISCUSSION OF RELATED ART

Semiconductor devices are essential elements in the electronics industry due to their attributes such as compactness, multi-functionality, and/or cost-effective manufacturing. These devices can include semiconductor memory devices that store logic data, semiconductor logic devices that process operations of logic data, and hybrid semiconductor devices that combine both memory and logic elements.

Recently, the demand for high speed and energy efficient electronic products has necessitated that semiconductor devices within them should have high operating speed and/or lower operating voltage. However, as the integration of semiconductor devices increases, this may cause a reduction in their electrical performance and production yield. Therefore, many studies have been directed towards enhancing the electrical properties and production yield of semiconductor devices.

### SUMMARY

Some embodiments of the present inventive concept provide a semiconductor device with improved electrical properties.

According to some embodiments of the present inventive concept, there is provided a semiconductor device including: a substrate that includes a cell region and a peripheral region, wherein the cell region includes a cell active pattern; a cell gate structure on the cell active pattern; a bit-line structure electrically connected to the cell active pattern; a peripheral gate structure on the peripheral region; a peripheral etch stop layer on the peripheral gate structure; and a cover dielectric layer on the peripheral etch stop layer, wherein the bit-line structure includes: a bit-line conductive layer; a bit-line dielectric layer on the bit-line conductive layer; a cell etch stop layer on the bit-line dielectric layer; and a bit-line capping layer on the cell etch stop layer, wherein the peripheral gate structure includes: a peripheral gate conductive layer; and a peripheral gate capping layer on the peripheral gate conductive layer.

According to some embodiments of the present inventive concept, there is provided a semiconductor device including: a substrate that includes a cell region and a peripheral region, wherein the cell region includes a cell active pattern; a cell gate structure on the cell active pattern; a bit-line structure electrically connected to the cell active pattern; a peripheral gate structure on the peripheral region; a peripheral etch stop layer on the peripheral gate structure; and a cover dielectric layer on the peripheral etch stop layer, wherein the bit-line structure includes: a bit-line conductive layer; a bit-line dielectric layer on the bit-line conductive layer; a cell etch stop layer on the bit-line dielectric layer; and a bit-line capping layer on the cell etch stop layer, wherein the peripheral gate structure includes: a peripheral gate conductive layer; a peripheral gate capping layer on the peripheral gate conductive layer; and a gate sidewall capping structure in contact with the peripheral etch stop layer and a sidewall of the peripheral gate conductive layer, wherein the gate sidewall capping structure includes nitride.

According to some embodiments of the present inventive concept, there is provided a semiconductor device including: a substrate that includes a cell region, a dummy region, and a peripheral region, wherein the cell region includes a cell active pattern; a cell gate structure on the cell active pattern; a dielectric structure on the dummy region and the peripheral region; a bit-line structure electrically connected to the cell active pattern; a dummy line structure that overlaps the dummy region; a peripheral gate structure on the peripheral region; a node contact on the cell active pattern; a landing pad on the node contact; a peripheral etch stop layer on the peripheral gate structure; and a cover dielectric layer on the peripheral etch stop layer, wherein the bit-line structure includes: a bit-line conductive layer; a bit-line dielectric layer on the bit-line conductive layer; and a bit-line capping layer on the bit-line dielectric layer, wherein the dummy line structure includes: a dummy line conductive layer; and a dummy line capping layer on the dummy line conductive layer, wherein the peripheral gate structure includes: a peripheral gate conductive layer; and a peripheral gate capping layer on the peripheral gate conductive layer, wherein the peripheral etch stop layer is in contact the dummy line capping layer and the peripheral gate capping layer, wherein the peripheral etch stop layer, the dummy line capping layer, and the peripheral gate capping layer include hydrogen and carbon, wherein a hydrogen concentration of the peripheral etch stop layer is different from a hydrogen concentration of the dummy line capping layer and a hydrogen concentration of the peripheral gate capping layer, and wherein a carbon concentration of the peripheral etch stop layer is different from a carbon concentration of the dummy line capping layer and a carbon concentration of the peripheral gate capping layer.

### BRIEF DESCRIPTION OF THE DRAWINGS

FIG. 1A illustrates a plan view showing a semiconductor device according to some embodiments of the present inventive concept.

FIG. 1B illustrates an enlarged view showing section E1 of FIG. 1A.

FIG. 1C illustrates a cross-sectional view taken along line A-A′ of FIG. 1B.

FIG. 1D illustrates a cross-sectional view taken along line B-B′ of FIG. 1B.

FIG. 1E illustrates an enlarged view showing section F1 of FIG. 1C.

FIG. 1F illustrates a cross-sectional view taken along line C-C′ of FIG. 1B.

FIGS. 2A, 2B, 2C, 3A, 3B, 4A, 4B, 4C, 5A, 5B, 6A, 6B, 6C, 7A, and 7B illustrate cross-sectional views showing a method of fabricating a semiconductor device according to FIGS. 1A to 1F.

FIGS. 8A, 8B, and 8C illustrate plan views showing a semiconductor device according to some embodiments of the present inventive concept.

FIGS. 9A, 9B, and 9C illustrate plan views showing a semiconductor device according to some embodiments of the present inventive concept.

FIGS. 10A, 10B, and 10C illustrate plan views showing a semiconductor device according to some embodiments of the present inventive concept.

FIGS. 11A, 11B, and 11C illustrate plan views showing a semiconductor device according to some embodiments of the present inventive concept.

### DETAILED DESCRIPTION OF THE EMBODIMENTS

It will be hereinafter discussed a semiconductor device and a method of fabricating the same according to some embodiments of the present inventive concept in conjunction with the accompanying drawings.

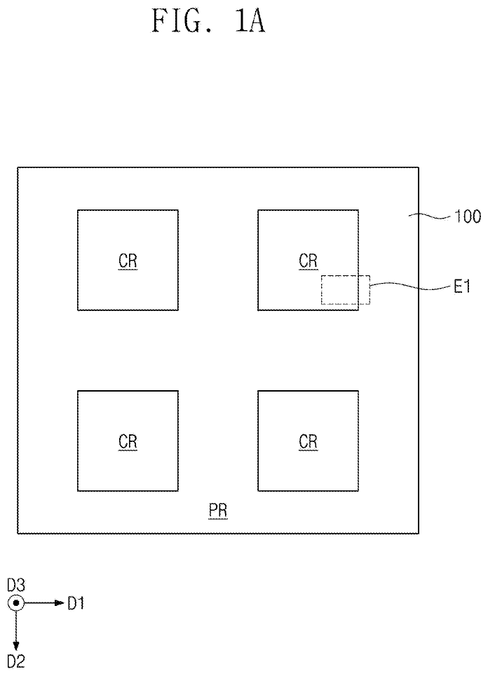

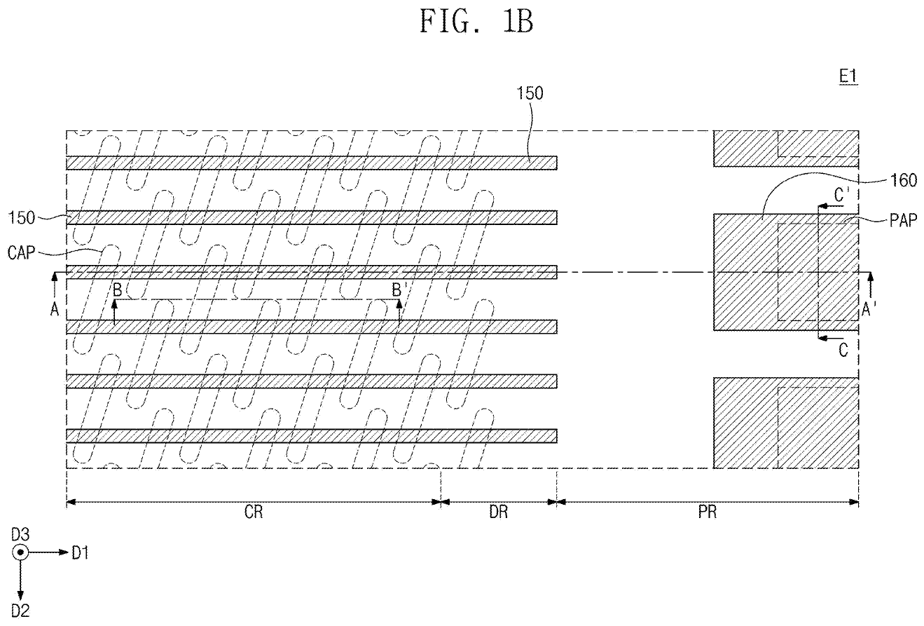

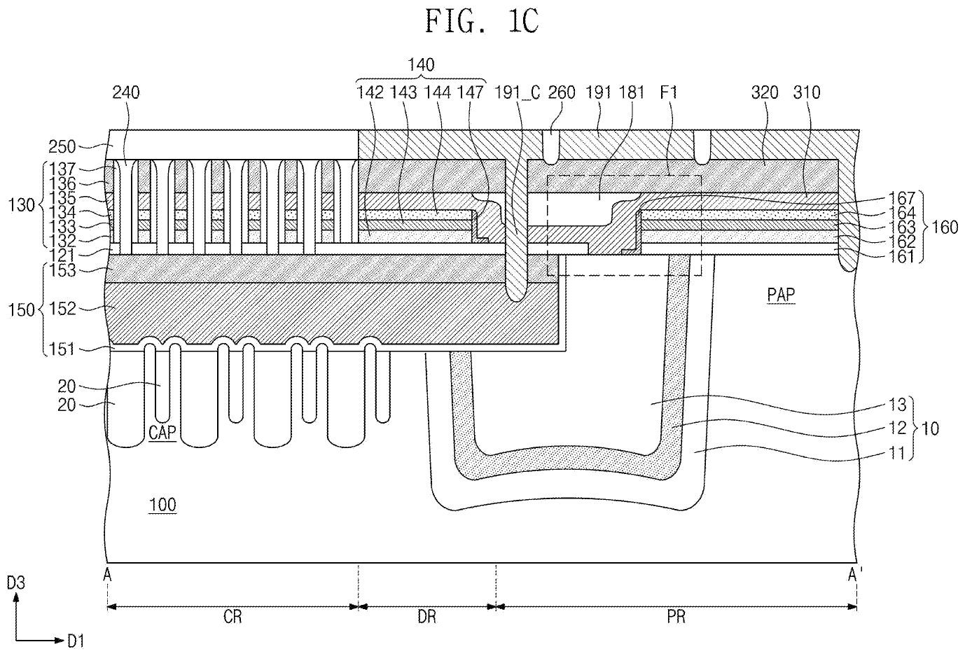

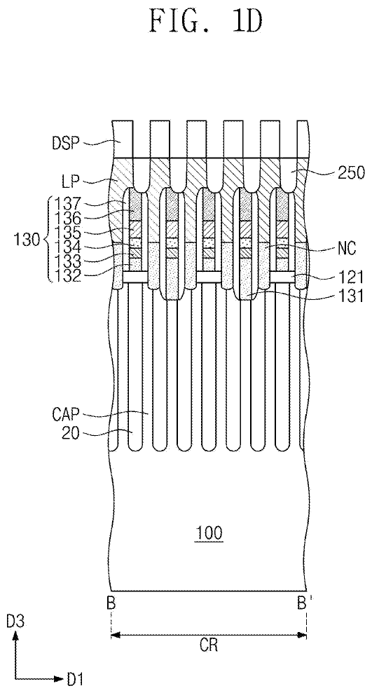

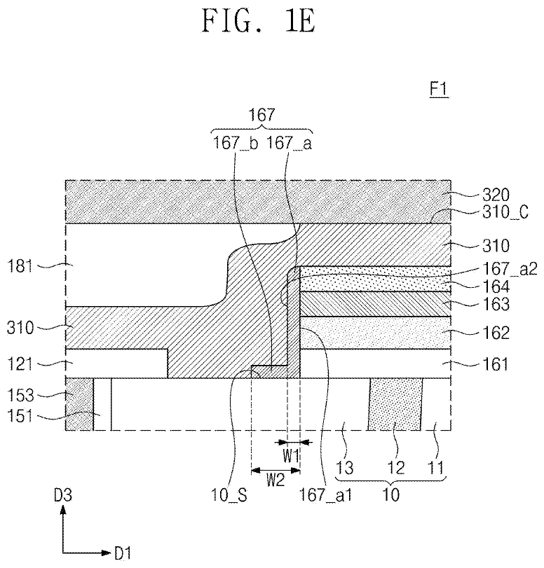

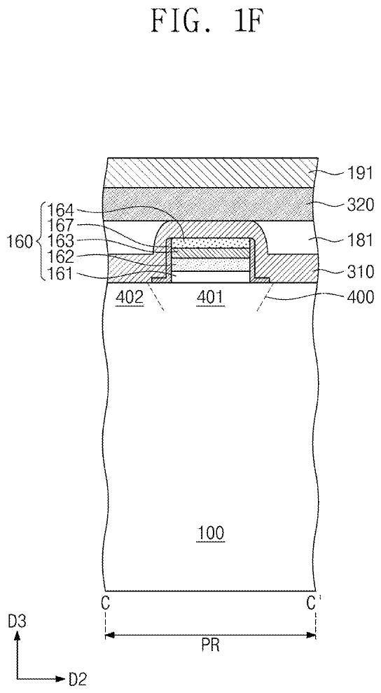

FIG. 1A illustrates a plan view showing a semiconductor device according to some embodiments of the present inventive concept. FIG. 1B illustrates an enlarged view showing section E1 of FIG. 1A. FIG. 1C illustrates a cross-sectional view taken along line A-A′ of FIG. 1B. FIG. 1D illustrates a cross-sectional view taken along line B-B′ of FIG. 1B. FIG. 1E illustrates an enlarged view showing section F1 of FIG. 1C. FIG. 1F illustrates a cross-sectional view taken along line C-C′ of FIG. 1B.

Referring to FIGS. 1A, 1B, 1C, 1D, 1E, and 1F, a semiconductor device may include a substrate 100. In some embodiments, the substrate 100 may be a semiconductor substrate. For example, the substrate 100 may include a silicon substrate, a germanium substrate, a silicon-germanium substrate, or a III-V group compound (e.g., GaP or GaAs) substrate. In some embodiments, the substrate 100 may be a silicon-on-insulator (SOI) substrate or a germanium-on-insulator (GOI) substrate. The substrate 100 may have a plate shape that extends along a plane expanding in a first direction D1 and a second direction D2. The first direction D1 and the second direction D2 may intersect each other. For example, the first direction D1 and the second direction D2 may be horizontal directions that are orthogonal to each other.

The substrate 100 may include cell regions CR and a peripheral region PR that surrounds the cell regions CR. The substrate 100 may further include a dummy region DR between the cell region CR and the peripheral region PR. When viewed in a plan view, the cell region CR, the dummy region DR, and the peripheral region PR may be distinguished from each other in the first direction D1 and the second direction D2.

The substrate 100 may include cell active patterns CAP on the cell region CR. The cell region CR of the substrate 100 may include upper portions that protrude in the third direction D3, and the cell active patterns CAP may be used to identify the protruding upper portions of the cell region CR. The third direction D3 may intersect the first direction D1 and the second direction D2. For example, the third direction D3 may be a vertical direction perpendicular to the first direction D1 and the second direction D2. The cell active patterns CAP may be spaced apart from each other.

A device isolation layer 20 may be provided which defines the cell active patterns CAP. The device isolation layer 20 may be provided on the cell region CR of the substrate 100. The device isolation layer 20 may surround each of the cell active patterns CAP. The device isolation layer 20 may include a dielectric material. For example, the device isolation layer 20 may include one or more of oxide and nitride.

A dielectric structure 10 may be provided in the substrate 100. The dielectric structure 10 may be provided between the cell region CR and the peripheral region PR. The dielectric structure 10 may be provided between the dummy region DR and the peripheral region PR. For example, the dielectric structure 10 may overlap the dummy region DR and the peripheral region PR. The dielectric structure 10 may include a first dielectric layer 11, a second dielectric layer 12 on the first dielectric layer 11, and a third dielectric layer 13 on the second dielectric layer 12. For example, the first dielectric layer 11 may include oxide, the second dielectric layer 12 may include nitride, and the third dielectric layer 13 may include oxide.

There may be provided cell gate structures 150 that extend in the first direction D1. The cell gate structures 150 may be arranged in the second direction D2. The cell gate structure 150 may be provided on the cell region CR and the dummy region DR of the substrate 100. The cell gate structure 150 may be provided on the device isolation layer 20, the dielectric structure 10, and the cell active patterns CAP. The cell gate structure 150 may be a buried gate structure that is buried in the device isolation layer 20, the dielectric structure 10, and the cell active patterns CAP. The cell gate structure 150 and the cell active pattern CAP may form a cell transistor.

The cell gate structure 150 may include a cell gate dielectric layer 151 on the cell active pattern CAP, a cell gate conductive layer 152 on the cell gate dielectric layer 151, and a cell gate capping layer 153 on the cell gate conductive layer 152.

The cell gate dielectric layer 151 and the cell gate capping layer 153 may include a dielectric material. For example, the cell gate dielectric layer 151 may include oxide, and the cell gate capping layer 153 may include nitride. The cell gate conductive layer 152 may include a conductive material. For example, the cell gate conductive layer 152 may include metal.

A dielectric pattern 121 may be provided on the dielectric structure 10, the device isolation layer 20, and the cell gate capping layer 153 of the cell gate structure 150. The dielectric pattern 121 may include a dielectric material. In some embodiments, the dielectric pattern 121 may include a plurality of dielectric layers.

The substrate 100 may include a peripheral active pattern PAP on the peripheral region PR. The peripheral region PR of the substrate 100 may have upper portions that protrude in the third direction D3, and the peripheral active patterns PAP may be provided to identify the protruding upper portions of the peripheral region PR.

A peripheral gate structure 160 may be provided on the peripheral region PR of the substrate 100. The peripheral gate structure 160 may be provided on the peripheral active pattern PAP. In some embodiments, the peripheral gate structure 160 may be a gate of a transistor that constitutes a sub-word line driver.

The peripheral gate structure 160 may include a peripheral gate dielectric layer 161, a first peripheral gate conductive layer 163, a second peripheral gate conductive layer 162, a peripheral gate capping layer 164, and a gate sidewall capping structure 167. The second peripheral gate conductive layer 162 may be disposed on the peripheral gate dielectric layer 161, the first peripheral gate conductive layer 163 may be disposed on the second peripheral gate conductive layer 162, and the peripheral gate capping layer 164 may be disposed on the first peripheral gate conductive layer 163.

The peripheral gate dielectric layer 161 may include a dielectric material. In some embodiments, the peripheral gate dielectric layer 161 may include a plurality of dielectric layers. For example, the peripheral gate dielectric layer 161 may include a silicon oxide (SiO2) layer and a hafnium oxide (HfO) layer. The second peripheral gate conductive layer 162 may include a conductive material. For example, the second peripheral gate conductive layer 162 may include one or more of titanium nitride and polysilicon. The first peripheral gate conductive layer 163 may include a conductive material. For example, the first peripheral gate conductive layer 163 may include tungsten (W). The peripheral gate capping layer 164 may include a dielectric material. For example, the peripheral gate capping layer 164 may include nitride.

Referring to FIG. 1E, the gate sidewall capping structure 167 may be provided on the dielectric structure 10. The gate sidewall capping structure 167 may include an upper part 167_a and a lower part 167_b. The upper part 167_a of the gate sidewall capping structure 167 may include a first sidewall 167_a1 and a second sidewall 167_a2. The first sidewall 167_a1 of the gate sidewall capping structure 167 may be in contact with a sidewall of the peripheral gate dielectric layer 161, a sidewall of the second peripheral gate conductive layer 162, a sidewall of the first peripheral gate conductive layer 163, and a sidewall of the peripheral gate capping layer 164. In other words, the first sidewall 167_a1 of the gate sidewall capping structure 167 is in direct contact with a sidewall of the peripheral gate structure 160. The second sidewall 167_a2 of the upper part 167_a included in the gate sidewall capping structure 167 may be in contact with a peripheral etch stop layer 310 which will be discussed below. The lower part 167_b of the gate sidewall capping structure 167 may be in contact with a top surface 10_S of the dielectric structure 10. For example, the lower part 167_b of the gate sidewall capping structure 167 may be in contact with a top of the third dielectric layer 13. The upper part 167_a of the gate sidewall capping structure 167 may have a width less than that of the lower part 167_b of the gate sidewall capping structure 167. For example, a width W1 in the first direction D1 of the upper part 167_a of the gate sidewall capping structure 167 may be less than a width W2 in the first direction D1 of the lower part 167_b of the gate sidewall capping structure 167.

The gate sidewall capping structure 167 may include a dielectric material. For example, the gate sidewall capping structure 167 may include nitride. The gate sidewall capping structure 167 may not include oxide. The gate sidewall capping structure 167 may include a plurality of dielectric layers.

Referring to FIG. 1F, the peripheral active pattern PAP may include a lattice defect pattern 400. The lattice defect pattern 400 may be provided in the peripheral active pattern PAP. For example, the lattice defect pattern 400 may include a dislocation or a grain boundary. The peripheral active pattern PAP may include a first part 401 and a second part 402 disposed on opposite sides of the lattice defect pattern 400. A lattice of the first part 401 and a lattice of the second part 402 may be in disagreement with each other. Referring to FIGS. 1A, 1B, 1C, 1D, 1E, and 1F, a dummy line structure 140 may be provided. The dummy line structure 140 may overlap the dummy region DR. The dummy line structure 140 may extend in the second direction D2. The dummy line structure 140 may be provided on the dielectric pattern 121. The dummy line structure 140 may include a first dummy line conductive layer 143, a second dummy line conductive layer 142, a dummy line capping layer 144, and a dummy line sidewall capping structure 147. The second dummy line conductive layer 142 may be provided on the dielectric pattern 121, the first dummy line conductive layer 143 may be provided on the second dummy line conductive layer 142, and the dummy line capping layer 144 may be provided on the first dummy line conductive layer 143.

The dummy line sidewall capping structure 147 may be in contact with a sidewall of the dummy line capping layer 144. The dummy line sidewall capping structure 147 may be in contact with a sidewall of each of the first and second dummy line conductive layers 143 and 142. The dummy line sidewall capping structure 147 may be in contact with a top surface of the dielectric pattern 121. The dummy line sidewall capping structure 147 may separate the sidewall of the dummy line capping layer 144 from a peripheral etch stop layer 310 which will be discussed below.

The second dummy line conductive layer 142, the first dummy line conductive layer 143, the dummy line capping layer 144, and the dummy line sidewall capping structure 147 of the dummy line structure 140 may be respectively similar to the second peripheral gate conductive layer 162, the first peripheral gate conductive layer 163, the peripheral gate capping layer 164, and the gate sidewall capping structure 167 of the peripheral gate structure 160.

The peripheral etch stop layer 310 may be provided on the dielectric pattern 121, the dummy line structure 140, and the peripheral gate structure 160. The peripheral etch stop layer 310 may extend in the first direction D1. The peripheral etch stop layer 310 may include a dielectric material. For example, the peripheral etch stop layer 310 may include nitride.

The peripheral etch stop layer 310 may cover the dummy line structure 140 and the peripheral gate structure 160. The peripheral etch stop layer 310 may be in contact with a top surface of the peripheral gate capping layer 164 and a top surface of the dummy line capping layer 144. The gate sidewall capping structure 167 may separate, from the peripheral etch stop layer 310, the sidewall of each of the peripheral gate dielectric layer 161, the second peripheral gate conductive layer 162, the first peripheral gate conductive layer 163, and the peripheral gate capping layer 164. The dummy line sidewall capping structure 147 may separate, from the peripheral etch stop layer 310, a sidewall of the second dummy line conductive layer 142, a sidewall of the first dummy line conductive layer 143, and a sidewall of the dummy line capping layer 144.

A filling dielectric layer 181 may be provided on the peripheral etch stop layer 310. The filling dielectric layer 181 may have top surface at the same level as that of a top surface of the peripheral etch stop layer 310. The filling dielectric layer 181 may include a dielectric material.

A cover dielectric layer 320 may be provided on the filling dielectric layer 181 and the peripheral etch stop layer 310. The peripheral etch stop layer 310 may include a contact surface 310_C in contact with a bottom surface of the cover dielectric layer 320. The contact surface 310_C of the peripheral etch stop layer 310 may overlap the peripheral gate structure 160. The cover dielectric layer 320 may extend in the first direction D1. The cover dielectric layer 320 may include a dielectric material. For example, the cover dielectric layer 320 may include nitride.

Conductive structures 191 may be provided on the cover dielectric layer 320. The conductive structures 191 may include a conductive material. At least one of the conductive structures 191 may include a conductive contact 191_C electrically connected to the cell gate structure 150. The conductive contact 191_C may be disposed in a recess formed on top of the cell gate structure 150. At least one of the conductive structures 191 may include a conductive contact 191_C electrically connected to the peripheral active pattern PAP.

First separation structures 260 may be provided on the cover dielectric layer 320. The first separation structure 260 may separate the conductive structures 191 from each other. The first separation structure 260 may include a dielectric material. In some embodiments, the first separation structures 260 and a subsequently described second separation structure 250 may be connected into a single unitary structure with no boundary therebetween.

There may be provided bit-line structures 130 that extend in the second direction D2. The bit-line structures 130 may be arranged in the first direction D1. The bit-line structure 130 may be provided on the cell region CR of the substrate 100. The bit-line structure 130 may be provided on the dielectric pattern 121 and the cell active pattern CAP. The bit-line structure 130 may be electrically connected to the cell active pattern CAP.

Each of the bit-line structures 130 may include bit-line contacts 131, a first bit-line conductive layer 133, a second bit-line conductive layer 132, a bit-line dielectric layer 134, a cell etch stop layer 135, a bit-line capping layer 136, and a bit-line spacer 137.

The bit-line contacts 131 of one bit-line structure 130 may be arranged in the second direction D2. The second bit-line conductive layers 132 of one bit-line structure 130 may be arranged in the second direction D2. The bit-line contacts 131 and the second bit-line conductive layers 132 of one bit-line structure 130 may be alternately disposed along the first direction D1. The bit-line contact 131 may be disposed on the cell active pattern CAP. The bit-line contact 131 may penetrate the dielectric pattern 121.

The second bit-line conductive layer 132 may be provided on the dielectric pattern 121. The bottom of the second bit-line conductive layer 132 may be higher than the bottom of the bit-line contact 131. The first bit-line conductive layer 133 may be provided on the second bit-line conductive layer 132. The bit-line dielectric layer 134 may be provided on the first bit-line conductive layer 133. The cell etch stop layer 135 may be provided on the bit-line dielectric layer 134. The bit-line capping layer 136 may be provided on the cell etch stop layer 135.

As discussed above, the peripheral etch stop layer 310 may include the contact surface 310_C in contact with the bottom surface of the cover dielectric layer 320. The cell etch stop layer 135 may have a top surface at the same level as that the contact surface 310_C of the peripheral etch stop layer 310.

In terms of material and thickness, the first bit-line conductive layer 133, the second bit-line conductive layer 132, and the bit-line dielectric layer 134 of the bit-line structure 130 may be similar to the first peripheral gate conductive layer 163, the second peripheral gate conductive layer 162, and the peripheral gate capping layer 164 of the peripheral gate structure 160. The cell etch stop layer 135 may include the same material as that of the peripheral etch stop layer 310. For example, the cell etch stop layer 135 may include nitride. In some embodiments, the cell etch stop layer 135 may have a thickness the same as that of the peripheral etch stop layer 310. For example, a thickness in the third direction D3 of the cell etch stop layer 135 may be the same as a thickness in the third direction D3 of a portion of the peripheral etch stop layer 310 that overlaps the peripheral gate structure 160.

The bit-line spacer 137 may cover a sidewall of the second bit-line conductive layer 132, a sidewall of the first bit-line conductive layer 133, a sidewall of the bit-line dielectric layer 134, a sidewall of the cell etch stop layer 135, and a sidewall of the bit-line capping layer 136. The bit-line spacer 137 may include a dielectric material. In some embodiments, the bit-line spacer 137 may include a plurality of dielectric layers.

The peripheral gate capping layer 164, the dummy line capping layer 144, the peripheral etch stop layer 310, and the cover dielectric layer 320 may include one or more of hydrogen and carbon. When the peripheral gate capping layer 164, the dummy line capping layer 144, the peripheral etch stop layer 310, and the cover dielectric layer 320 include hydrogen, a hydrogen concentration of the peripheral gate capping layer 164, the dummy line capping layer 144, and the cover dielectric layer 320 may be different from that of the peripheral etch stop layer 310. For example, the hydrogen concentration of the peripheral gate capping layer 164, the dummy line capping layer 144, and the cover dielectric layer 320 may be greater or less than that of the peripheral etch stop layer 310.

When the peripheral gate capping layer 164, the dummy line capping layer 144, the peripheral etch stop layer 310, and the cover dielectric layer 320 include carbon, a carbon concentration of the peripheral gate capping layer 164, the dummy line capping layer 144, and the cover dielectric layer 320 may be different from that of the peripheral etch stop layer 310. For example, the carbon concentration of the peripheral gate capping layer 164, the dummy line capping layer 144, and the cover dielectric layer 320 may be greater or less than that of the peripheral etch stop layer 310.

The bit-line capping layer 136, the cell etch stop layer 135, and the bit-line dielectric layer 134 may include one or more of hydrogen and carbon. When the bit-line capping layer 136, the cell etch stop layer 135, and the bit-line dielectric layer 134 include hydrogen, a hydrogen concentration of the bit-line capping layer 136 and the bit-line dielectric layer 134 may be different from that of the cell etch stop layer 135. For example, the hydrogen concentration of the bit-line capping layer 136 and the bit-line dielectric layer 134 may be greater or less than that of the cell etch stop layer 135.

When the bit-line capping layer 136, the cell etch stop layer 135, and the bit-line dielectric layer 134 include carbon, a carbon concentration of the bit-line capping layer 136 and the bit-line dielectric layer 134 may be different from that of the cell etch stop layer 135. For example, the carbon concentration of the bit-line capping layer 136 and the bit-line dielectric layer 134 may be greater or less than that of the cell etch stop layer 135.

Node contacts NC may be provided. The node contact NC may be provided on the cell active pattern CAP. The node contact NC may be provided between neighboring bit-line structures 130. The node contact NC may be provided on a sidewall of the bit-line structure 130. The node contact NC may include a conductive material. For example, the node contact NC may include polysilicon.

Landing pads LP may be provided. The landing pad LP may be provided on the node contact NC. The landing pad LP may be provided between neighboring bit-line structures 130. The landing pad LP may include a conductive material. For example, the landing pad LP may include metal. In some embodiments, a metal silicide layer may be provided between the node contact NC and the landing pad LP. In some embodiments, a barrier layer may be provided between the node contact NC and the landing pad LP.

Dielectric fences 240 may be provided. The dielectric fence 240 may be provided on the cell gate capping layer 153. For example, the dielectric fence 240 may be provided between neighboring bit-line structures 130 and contact the exposed cell gate capping layer 153 therebetween. The dielectric fence 240 may be provided between the node contacts NC that are adjacent to each other in the first direction D1. The dielectric fence 240 may include a dielectric material.

The second separation structure 250 may be provided on the dielectric fence 240. The second separation structure 250 may separate the landing pads LP from each other. The second separation structure 250 may surround the landing pad LP. The second separation structure 250 may include a dielectric material.

Data storage patterns DSP may be provided. For example, the data storage pattern DSP may be in direct contact with the landing pad LP. The data storage pattern DSP may be electrically connected to the cell active pattern CAP through the landing pad LP and the node contact NC. In some embodiments, each of the data storage patterns DSP may be a capacitor including a bottom electrode, a dielectric layer, and a top electrode. In this case, the semiconductor device including the data storage patterns DSP may be a dynamic random access memory (DRAM). In some embodiments, each of the data storage patterns DSP may include a magnetic tunnel junction pattern. In this case, the semiconductor device including the data storage patterns DSP may be a magnetic random access memory (MRAM). In some embodiments, the data storage patterns DSP may include a phase change material or a variable resistance material. In this case, the semiconductor device including the data storage patterns DSP may be a phase change random access memory (PRAM) or a resistive random access memory (ReRAM). In some embodiments, each of the data storage patterns DSP may include various materials and/or structures capable of storage data.

The first part 401 of the peripheral active pattern PAP may provide a path along which electrons or holes move. For example, the first part of the peripheral active pattern PAP may be disposed under the peripheral gate structure 160. The lattice defect pattern 400 may increase mobility of electrons or holes. The lattice defect pattern 400 may allow a peripheral transistor to have improved electrical properties.

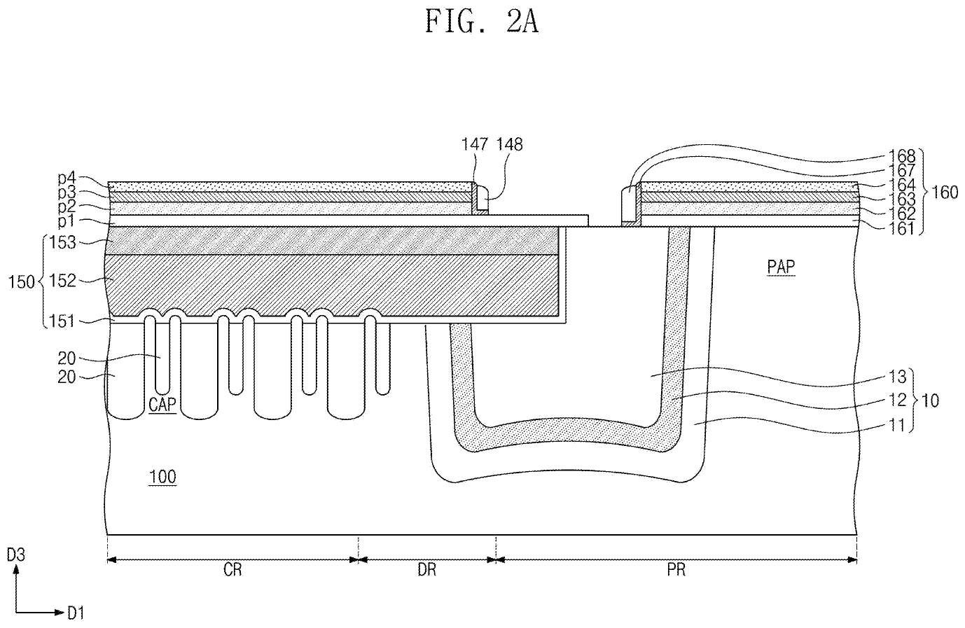

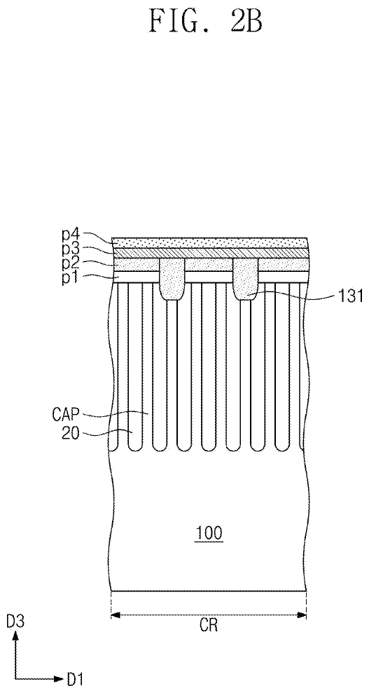

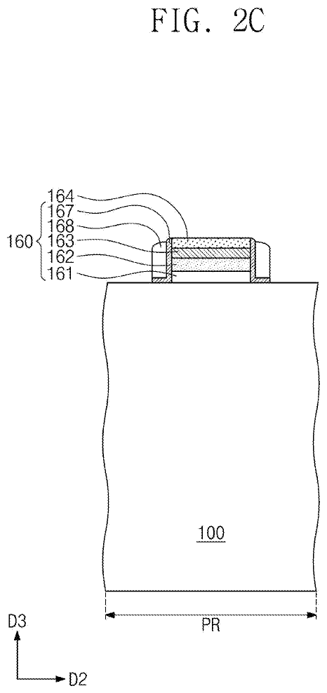

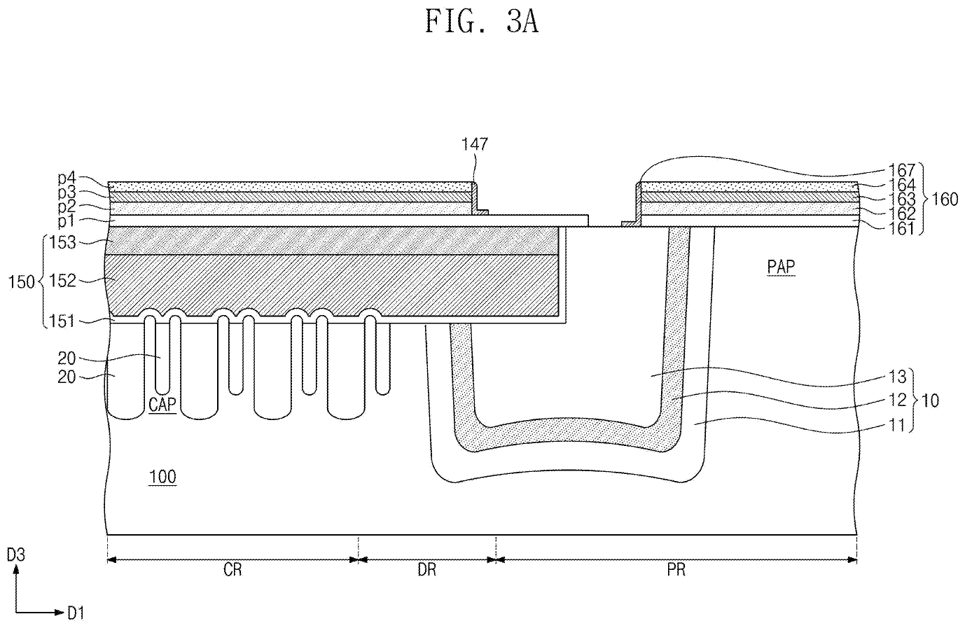

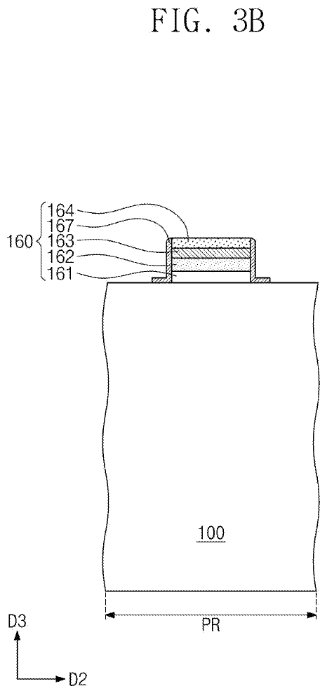

FIGS. 2A, 2B, 2C, 3A, 3B, 4A, 4B, 4C, 5A, 5B, 6A, 6B, 6C, 7A, and 7B illustrate cross-sectional views showing a method of fabricating a semiconductor device according to FIGS. 1A to 1F. FIGS. 2A, 3A, 4A, 5A, 6A, and 7A may correspond to FIG. 1C. FIGS. 2B, 4B, 6B, and 7B may correspond to FIG. 1D. FIGS. 3B, 5B, and 6C may correspond to FIG. 1F.

Referring to FIGS. 2A, 2B, and 2C, a substrate 100 may be provided which includes a cell region CR, a dummy region DR, and a peripheral region PR. A dielectric structure 10, a device isolation layer 20, and a cell gate structure 150 may be formed on the substrate 100. There may be formed cell active patterns CAP and peripheral active patterns PAP of the substrate 100.

A preliminary dielectric pattern p1, a bit-line contact 131, a first preliminary conductive layer p2 on the preliminary dielectric pattern p1, a second preliminary conductive layer p3 on the first preliminary conductive layer p2, and a preliminary capping layer p4 on the second preliminary conductive layer p3 may be formed on the cell region CR and the dummy region DR of the substrate 100. A peripheral gate structure 160 may be formed on the peripheral region PR of the substrate 100.

A dummy line sidewall capping structure 147 may be formed which is in contact with a sidewall of the first preliminary conductive layer p2, a sidewall of the second preliminary conductive layer p3, a sidewall of the preliminary capping layer p4, and a top surface of the preliminary dielectric pattern p1. A first sacrificial spacer 148 may be formed on the dummy line sidewall capping structure 147. The peripheral gate structure 160 may further include a second sacrificial spacer 168. The second sacrificial spacer 168 may be formed on a gate sidewall capping structure 167. The first sacrificial spacer 148 and the second sacrificial spacer 168 may be formed by deposition and etching processes. The first sacrificial spacer 148 and the second sacrificial spacer 168 may include a dielectric material. For example, the first sacrificial spacer 148 and the second sacrificial spacer 168 may include oxide.

Referring to FIGS. 3A and 3B, the first sacrificial spacer 148 and the second sacrificial spacer 168 may be removed. The first sacrificial spacer 148 and the second sacrificial spacer 168 may be removed by, for example, an etching process. The first sacrificial spacer 148 and the second sacrificial spacer 168 may be removed to expose the dummy line sidewall capping structure 147 and the gate sidewall capping structure 167.

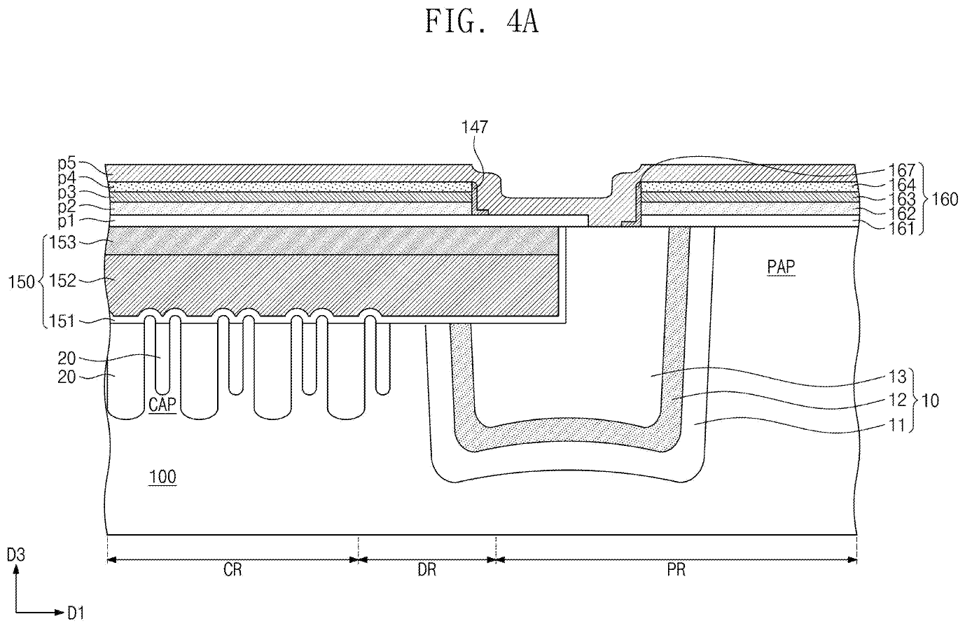

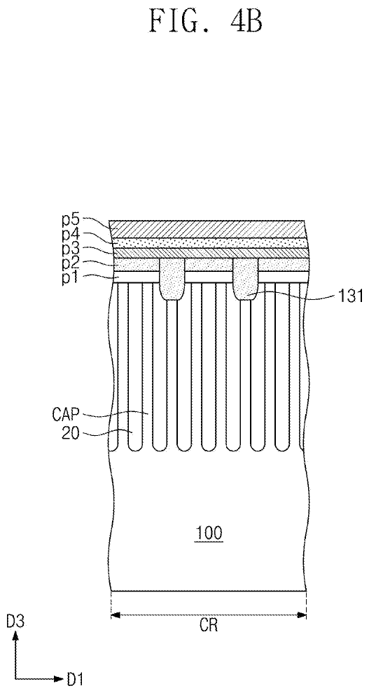

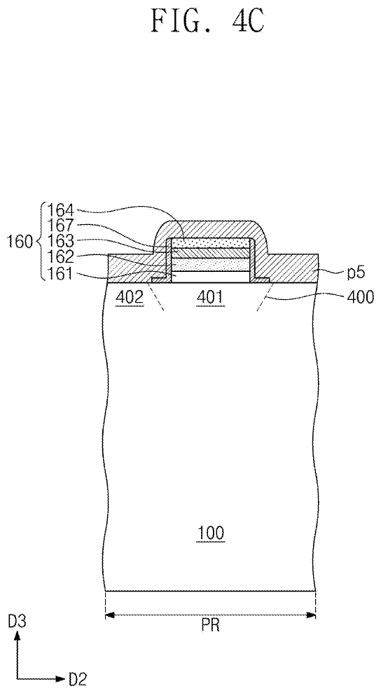

Referring to FIGS. 4A, 4B, and 4C, a preliminary peripheral etch stop layer p5 may be formed on the preliminary dielectric pattern p1, the preliminary capping layer p4, the dummy line sidewall capping structure 147, and the peripheral gate structure 160. The preliminary peripheral etch stop layer p5 may cover the peripheral gate structure 160. For example, the preliminary peripheral etch stop layer p5 may include nitride. The formation of the preliminary peripheral etch stop layer p5 may cause the formation of a lattice defect pattern 400 in the peripheral active pattern PAP. The preliminary peripheral etch stop layer p5 may include one or more of hydrogen and carbon. The hydrogen or carbon included in the preliminary peripheral etch stop layer p5 may provide the peripheral active pattern PAP with tensile stress or compressive stress. The tensile or compressive stress may form the lattice defect pattern 400.

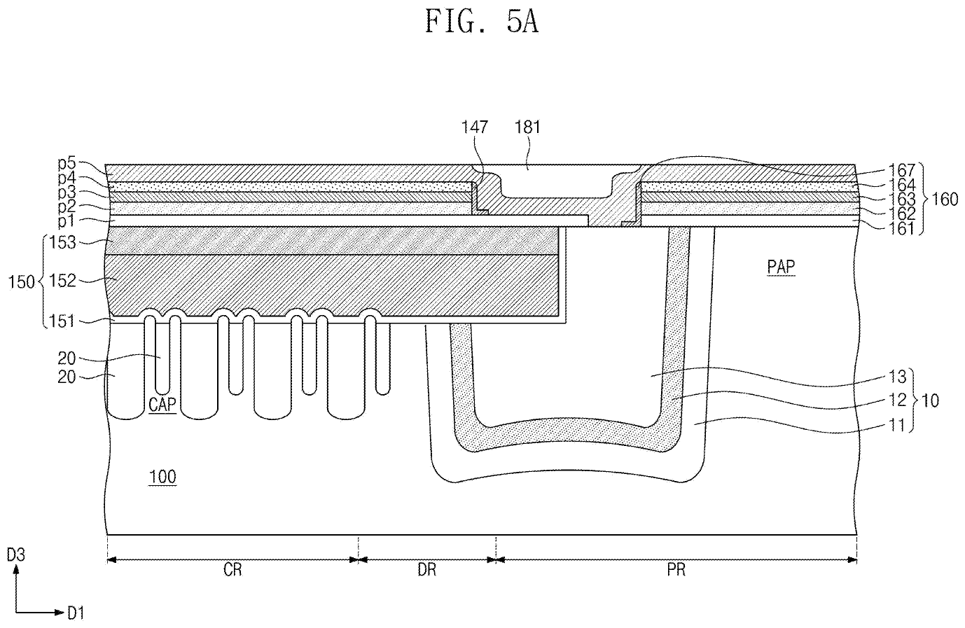

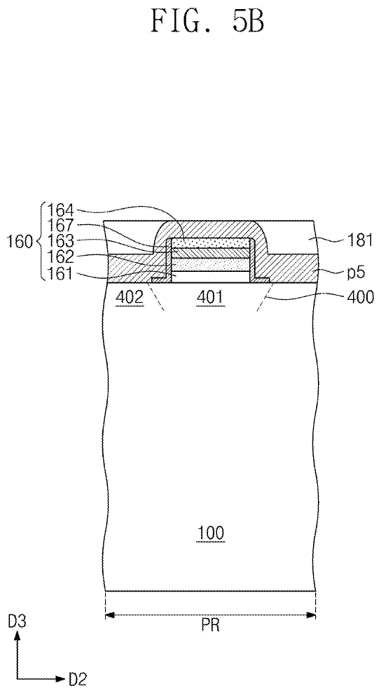

Referring to FIGS. 5A and 5B, a filling dielectric layer 181 may be buried on the preliminary peripheral etch stop layer p5. The filling dielectric layer 181 may fill a space overlapping the dielectric structure 10. The filling dielectric layer 181 may be located on opposite sides of the peripheral gate structure 160. In some embodiments, the formation of the filling dielectric layer 181 may include depositing a dielectric material and performing a chemical mechanical polishing process. For example, the filling dielectric layer 181 may include oxide.

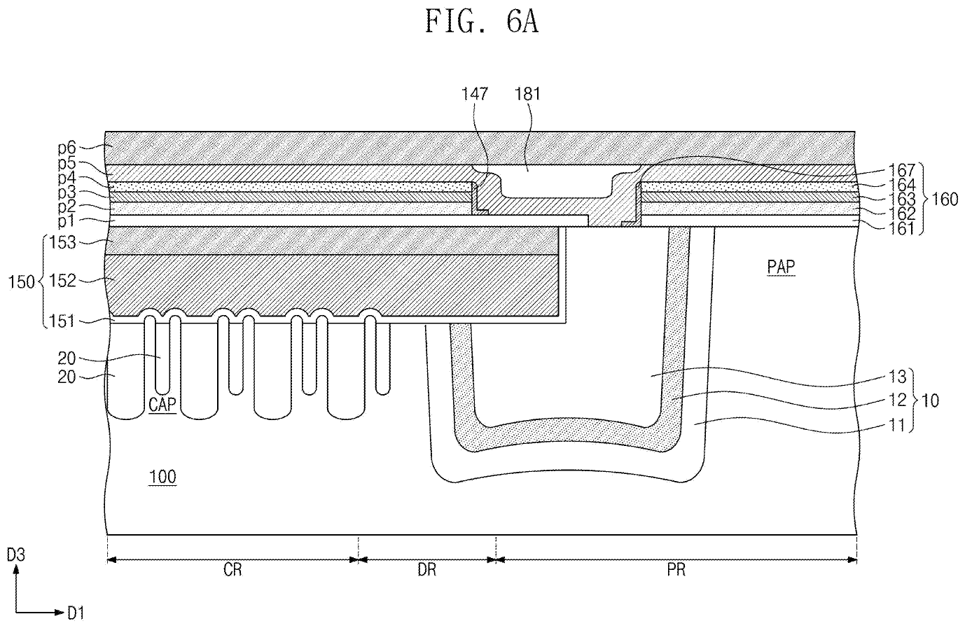

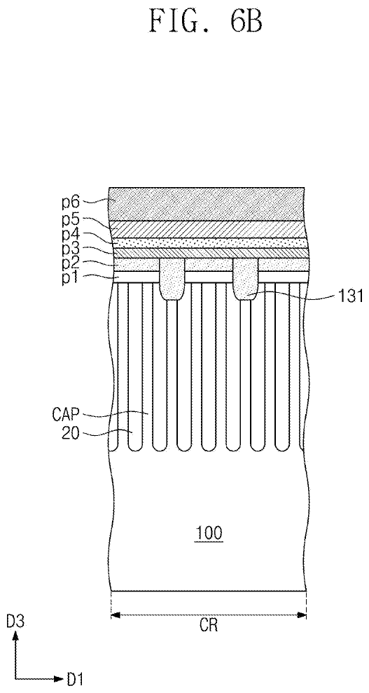

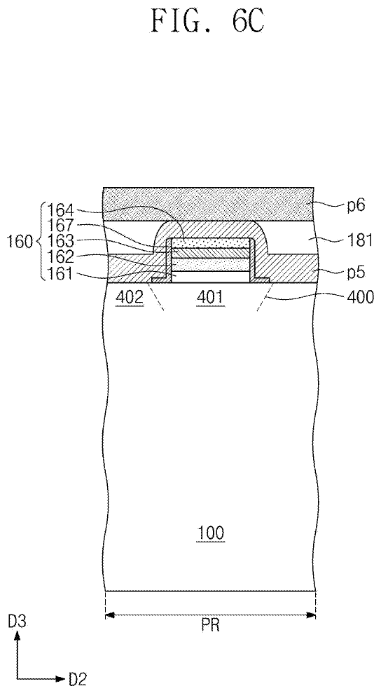

Referring to FIGS. 6A, 6B, and 6C, a preliminary cover dielectric layer p6 may be formed on the preliminary peripheral etch stop layer p5 and the filling dielectric layer 181. The preliminary cover dielectric layer p6 may include a dielectric material. For example, the preliminary cover dielectric layer p6 may include nitride.

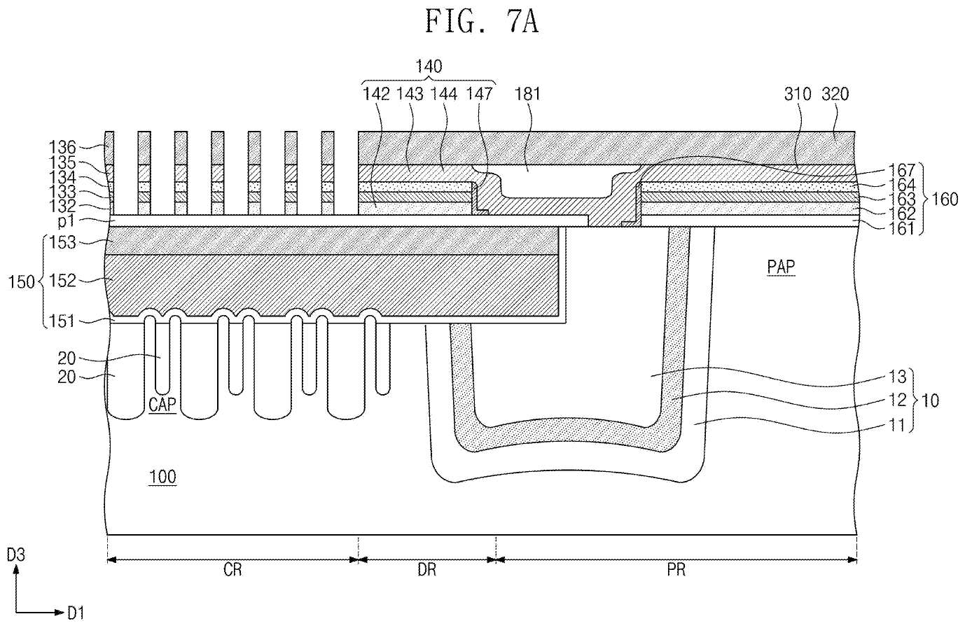

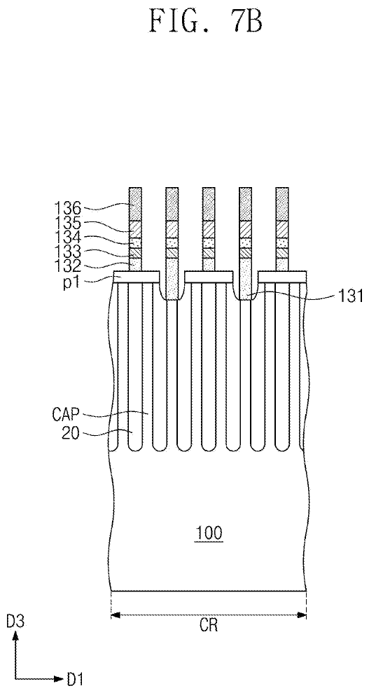

Referring to FIGS. 7A and 7B, a patterning process may be performed on the first preliminary conductive layer p2, the second preliminary conductive layer p3, the preliminary capping layer p4, the preliminary peripheral etch stop layer p5, and the preliminary cover dielectric layer p6. The first preliminary conductive layer p2 may be patterned to form second bit-line conductive layers 132 and a second dummy line conductive layer 142. The bit-line contact 131 may be patterned together with the second bit-line conductive layer 132. The second preliminary conductive layer p3 may be patterned to form first bit-line conductive layers 133 and a first dummy line conductive layer 143. The preliminary capping layer p4 may be patterned to form bit-line dielectric layers 134 and a dummy line capping layer 144. The preliminary peripheral etch stop layer p5 may be patterned to form cell etch stop layers 135 and a peripheral etch stop layer 310. The preliminary cover dielectric layer p6 may be patterned to form bit-line capping layers 136 and a cover dielectric layer 320.

There may be exposed a lateral surface of the second bit-line conductive layer 132, a lateral surface of the first bit-line conductive layer 133, a lateral surface of the bit-line dielectric layer 134, a lateral surface of the cell etch stop layer 135, and a lateral surface of the bit-line capping layer 136. In other words, trenches may be formed between protruded structures formed by the second bit-line conductive layer 132, the first bit-line conductive layer 133, the bit-line dielectric layer 134, the cell etch stop layer 135, and the bit-line capping layer 136.

Referring to FIGS. 1A, 1B, 1C, 1D, 1E, and 1F, the preliminary dielectric pattern p1 may be patterned to form a dielectric pattern 121. There may be formed bit-line spacers 137, dielectric fences 240, a second separation structure 250, node contacts NC, landing pads LP, data storage patterns DSP, conductive structures 191, and first separation structures 260.

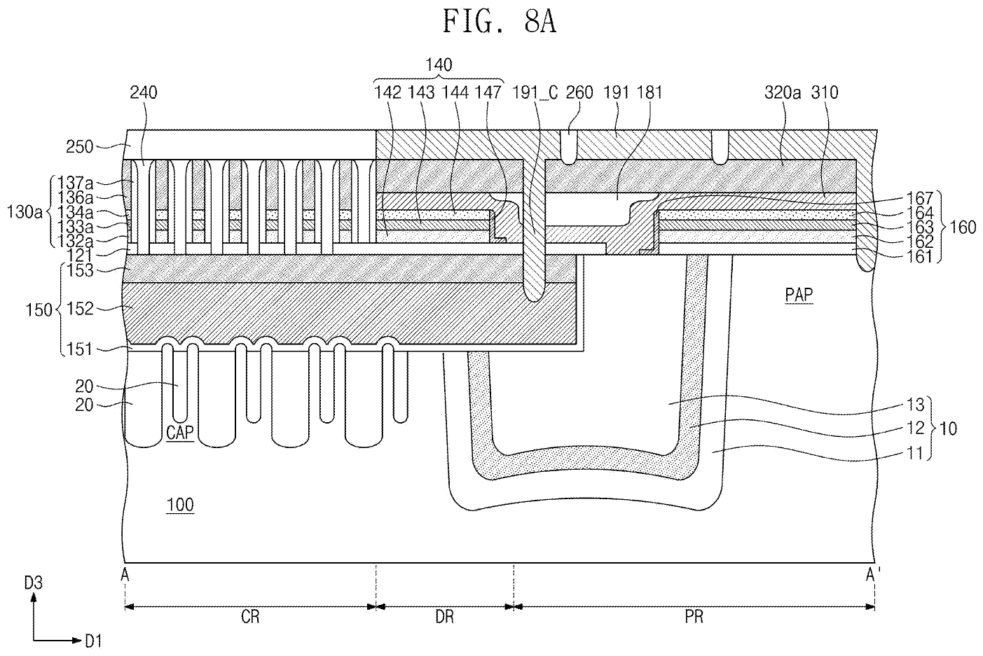

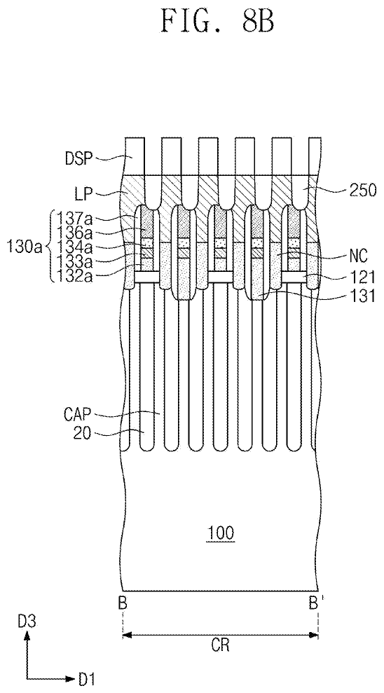

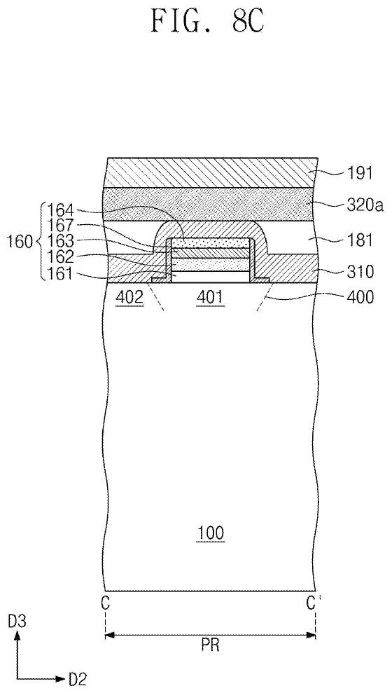

FIGS. 8A, 8B, and 8C illustrate plan views showing a semiconductor device according to some embodiments of the present inventive concept.

Referring to FIGS. 8A, 8B, and 8C, a bit-line structure 130a may include a second bit-line conductive layer 132a, a first bit-line conductive layer 133a on the second bit-line conductive layer 132a, a bit-line dielectric layer 134a on the first bit-line conductive layer 133a, a bit-line capping layer 136a on the bit-line dielectric layer 134a, and a bit-line spacer 137a.

A preliminary peripheral etch stop layer may be formed, a photoresist pattern may be formed to expose the cell region CR, and the photoresist pattern may be used as an etching mask to etch the preliminary peripheral etch stop layer on the cell region CR, with the result that the bit-line structure 130a may not include a cell etch stop layer. In other words, the bit-line stricture 130a may not include the cell etch stop layer 135.

Even though the bit-line structure 130a does not include a cell etch stop layer, a chemical mechanical polishing process may be performed to adjust a step difference between the bit-line capping layer 136a and the cover dielectric layer 320a. For example, the bit-line capping layer 136a of the bit-line structure 130a may have a top surface at the same level as that of a top surface of the cover dielectric layer 320a.

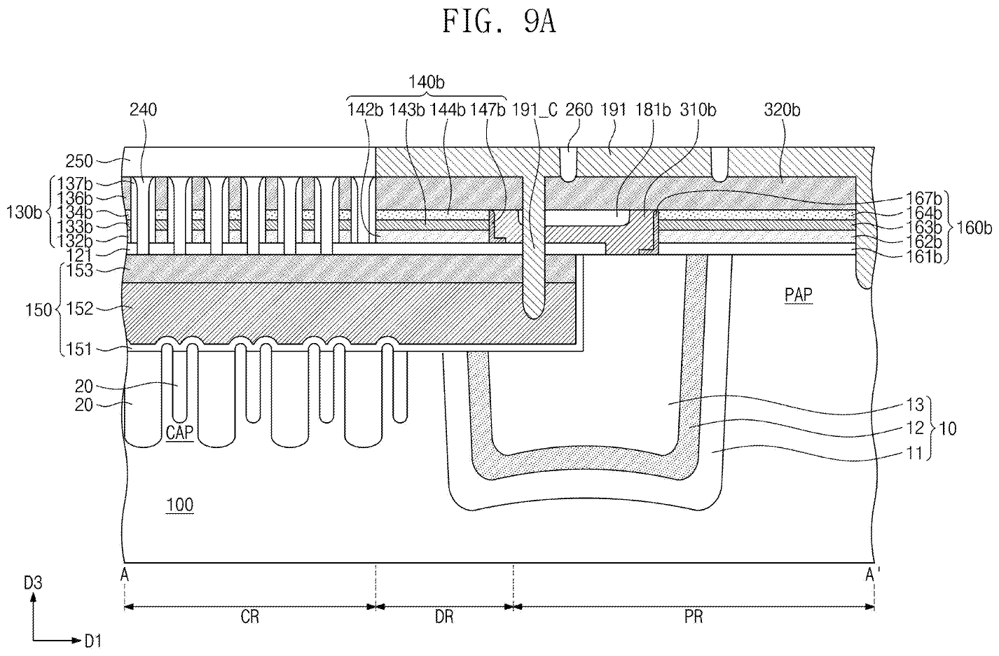

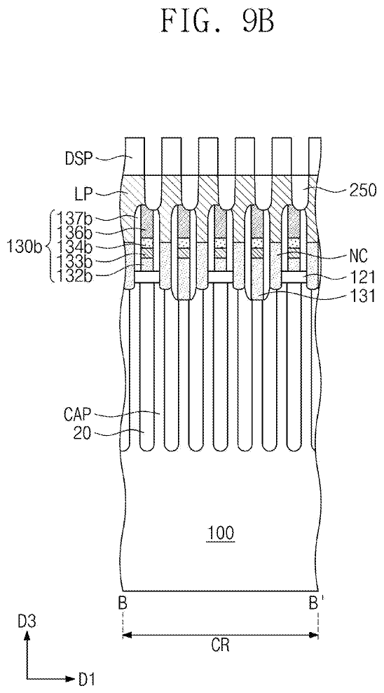

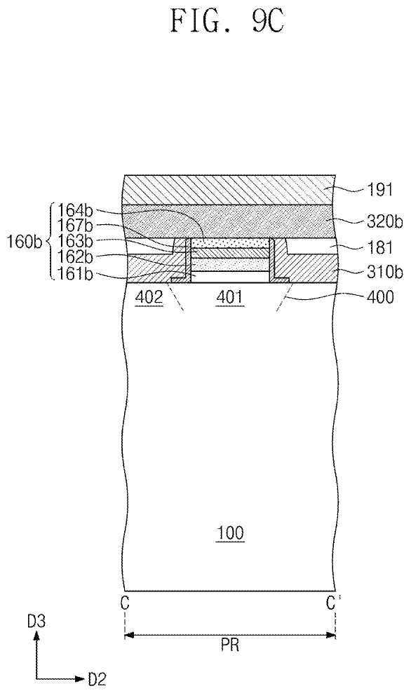

FIGS. 9A, 9B, and 9C illustrate plan views showing a semiconductor device according to some embodiments of the present inventive concept.

Referring to FIGS. 9A, 9B, and 9C, a bit-line structure 130b may include a second bit-line conductive layer 132b, a first bit-line conductive layer 133b on the second bit-line conductive layer 132b, a bit-line dielectric layer 134b on the first bit-line conductive layer 133b, a bit-line capping layer 136b on the bit-line dielectric layer 134b, and a bit-line spacer 137b. In other words, the bit-line structure 130b may not include an etch stop layer.

A dummy line structure 140b may include a first dummy line conductive layer 143b, a second dummy line conductive layer 142b, a dummy line capping layer 144b, and a dummy line sidewall capping structure 147b.

A peripheral gate structure 160b may include a peripheral gate dielectric layer 161b, a first peripheral gate conductive layer 163b, a second peripheral gate conductive layer 162b, a peripheral gate capping layer 164b, and a gate sidewall capping structure 167b.

The dummy line capping layer 144b and the peripheral gate capping layer 164b may have their top surfaces in contact with a cover dielectric layer 320b. A peripheral etch stop layer 310b may be spaced apart from the top surface of the dummy line capping layer 144b and the top surface of the peripheral gate capping layer 164b. The peripheral etch stop layer 310b may be provided between the dummy line structure 140b and the peripheral gate structure 160b. The peripheral etch stop layer 310b may not be located between the top of the peripheral gate structure 160b and the bottom of the cover dielectric layer 320b. The peripheral etch stop layer 310b may also not be located between the top of the dummy line structure 140b and the bottom of the cover dielectric layer 320b. The dummy line sidewall capping structure 147b and the gate sidewall capping structure 167b may have their top surfaces in contact with the cover dielectric layer 320b.

The dummy line capping layer 144b, the peripheral etch stop layer 310b, a filling dielectric layer 181b, and the peripheral gate capping layer 164b may have their top surfaces at the same level.

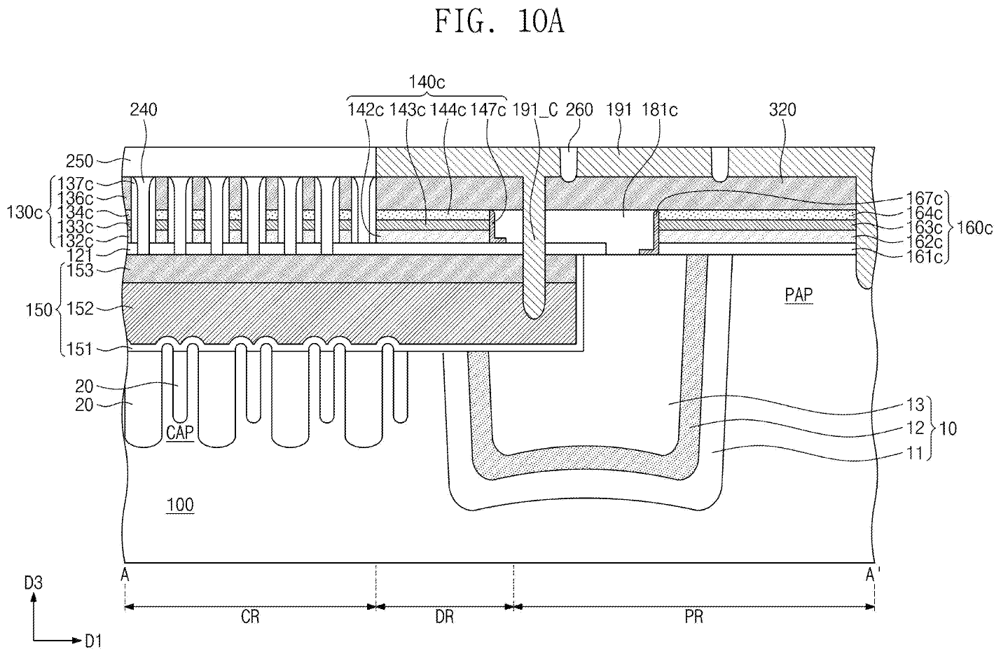

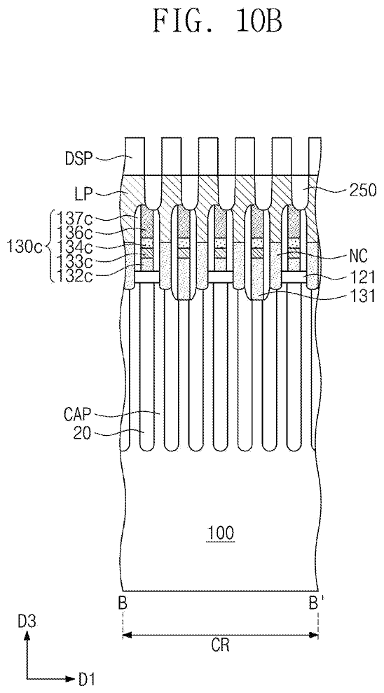

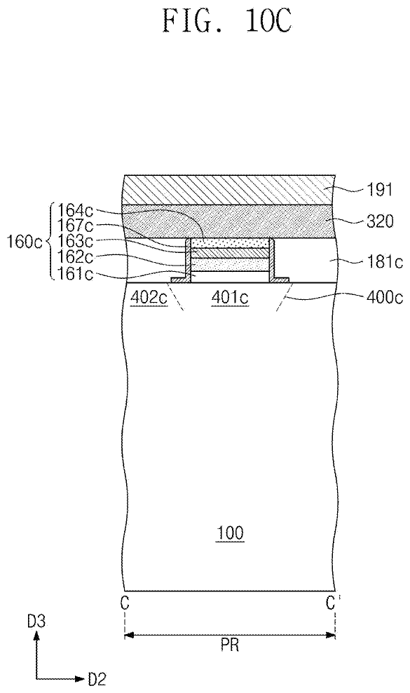

FIGS. 10A, 10B, and 10C illustrate plan views showing a semiconductor device according to some embodiments of the present inventive concept.

Referring to FIGS. 10A, 10B, and 10C, a bit-line structure 130c may include a second bit-line conductive layer 132c, a first bit-line conductive layer 133c on the second bit-line conductive layer 132c, a bit-line dielectric layer 134c on the first bit-line conductive layer 133c, a bit-line capping layer 136c on the bit-line dielectric layer 134c, and a bit-line spacer 137c.

A dummy line structure 140c may include a first dummy line conductive layer 143c, a second dummy line conductive layer 142c, a dummy line capping layer 144c, and a dummy line sidewall capping structure 147c.

A peripheral gate structure 160c may include a peripheral gate dielectric layer 161c, a first peripheral gate conductive layer 163c, a second peripheral gate conductive layer 162c, a peripheral gate capping layer 164c, and a gate sidewall capping structure 167c.

A preliminary peripheral etch stop layer may be etched such that the bit-line structure 130c may not include a cell etch stop layer. The preliminary peripheral etch stop layer may be etched such that neither the dummy region DR nor the peripheral region PR may include a peripheral etch stop layer. The dummy line capping layer 144c and the gate sidewall capping structure 167c may be in contact with a filling dielectric layer 181c.

A stress memorization technique (SMT) may be performed to allow the peripheral active pattern PAP to include a lattice defect pattern 400c even when the peripheral region PR does not include a peripheral etch stop layer. The peripheral active pattern PAP may include a first part 401c and a second part 402c that are disposed on opposite sides of the lattice defect pattern 400c. A lattice of the first part 401c and a lattice of the second part 402c may be in disagreement with each other. The first part 401c of the peripheral active pattern PAP may be overlapped by the peripheral gate structure 160c.

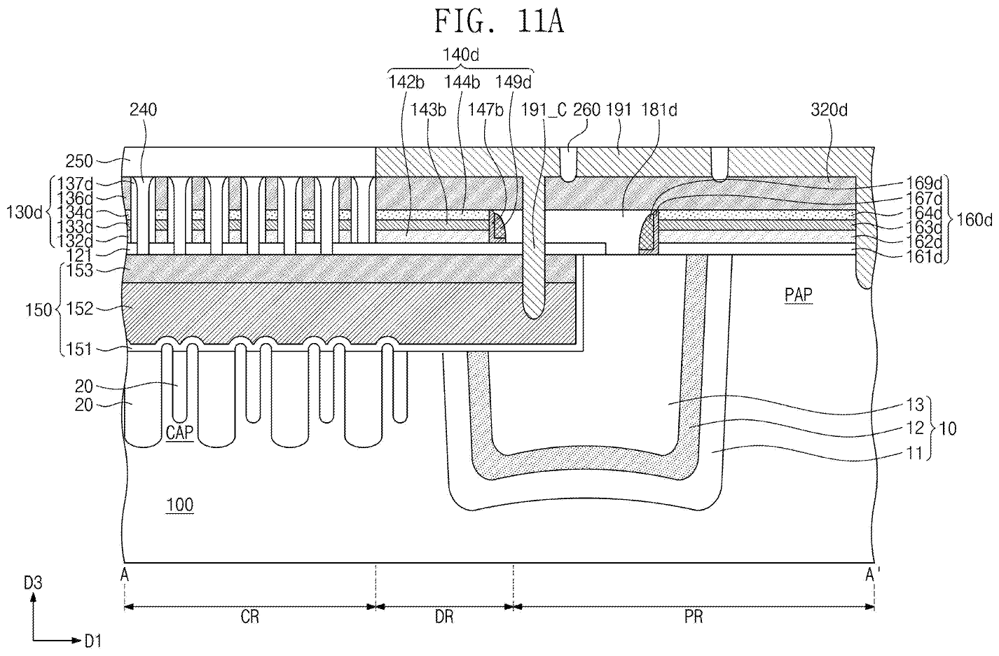

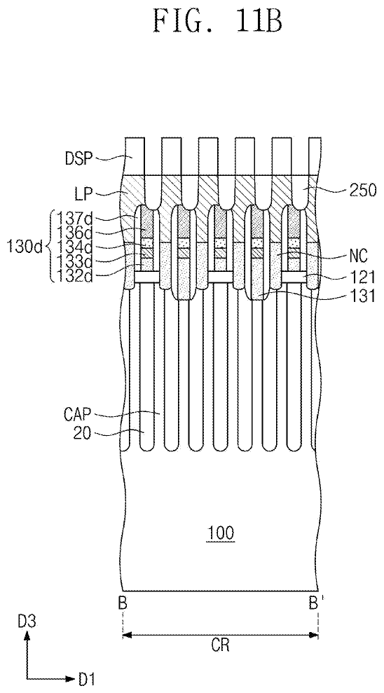

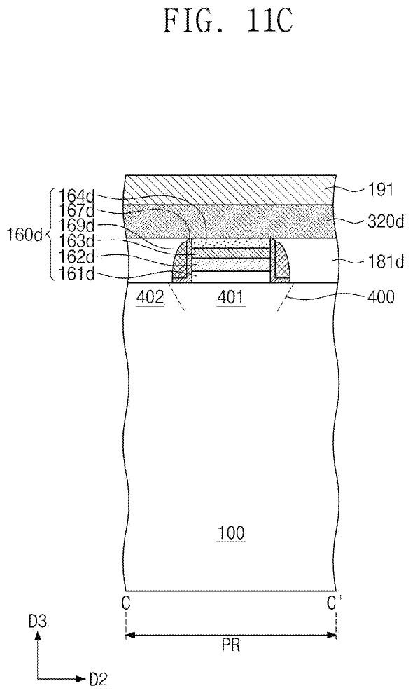

FIGS. 11A, 11B, and 11C illustrate plan views showing a semiconductor device according to some embodiments of the present inventive concept.

Referring to FIGS. 11A, 11B, and 11C, a bit-line structure 130d may include a second bit-line conductive layer 132d, a first bit-line conductive layer 133d on the second bit-line conductive layer 132d, a bit-line dielectric layer 134d on the first bit-line conductive layer 133d, a bit-line capping layer 136d on the bit-line dielectric layer 134d, and a bit-line spacer 137d.

A dummy line structure 140d may include a first dummy line conductive layer 143d, a second dummy line conductive layer 142d, a dummy line capping layer 144d, a dummy line sidewall capping structure 147d, and a dummy line etch stop spacer 149d.

A peripheral gate structure 160d may include a peripheral gate dielectric layer 161d, a first peripheral gate conductive layer 163d, a second peripheral gate conductive layer 162d, a peripheral gate capping layer 164d, a gate sidewall capping structure 167d, and a peripheral gate etch stop spacer 169d.

A preliminary peripheral etch stop layer may be etched such that the bit-line structure 130d may not include a cell etch stop layer. The bit-line dielectric layer 134d may have a top surface in contact with the bit-line capping layer 136d. The preliminary peripheral etch stop layer may be etched to provide the dummy line etch stop spacer 149d and the peripheral gate etch stop spacer 169d.

The dummy line etch stop spacer 149d may be provided on the dummy line sidewall capping structure 147d. The dummy line etch stop spacer 149d may be in contact with a sidewall of the dummy line sidewall capping structure 147d. The peripheral gate etch stop spacer 169d may be provided on the gate sidewall capping structure 167d. The peripheral gate etch stop spacer 169d may be in contact with a sidewall of the gate sidewall capping structure 167d. The dummy line etch stop spacer 149d and the peripheral gate etch stop spacer 169d may be in contact with a filling dielectric layer 181d. The dummy line etch stop spacer 149d and the peripheral gate etch stop spacer 169d may face each other with the conductive contact 191_C therebetween. The dummy line capping layer 144d and the peripheral gate capping layer 164b may have their top surfaces in contact with a cover dielectric layer 320d.

A semiconductor device according to some embodiments of the present inventive concept includes a lattice defect pattern formed by a peripheral etch stop layer. As a result, the mobility of electrons and holes can be enhanced, leading to improved electrical properties of a transistor on a peripheral region.

Although the present inventive concept has been described in connection with some example embodiments thereof, it will be understood by one of ordinary skill in the art that variations in form and detail may be made thereto. The above disclosed embodiments should thus be considered illustrative and not restrictive.

What is claimed is:

1. A semiconductor device, comprising:
a substrate that includes a cell region and a peripheral region, wherein the cell region includes a cell active pattern;
a cell gate structure on the cell active pattern;
a bit-line structure electrically connected to the cell active pattern;
a peripheral gate structure on the peripheral region;
a peripheral etch stop layer on the peripheral gate structure; and
a cover dielectric layer on the peripheral etch stop layer,
wherein the bit-line structure includes:
a bit-line conductive layer;
a bit-line dielectric layer on the bit-line conductive layer;
a cell etch stop layer on the bit-line dielectric layer; and
a bit-line capping layer on the cell etch stop layer,
wherein the peripheral gate structure includes:
a peripheral gate conductive layer; and
a peripheral gate capping layer on the peripheral gate conductive layer.

2. The semiconductor device of claim 1, wherein
the cell etch stop layer, the bit-line dielectric layer, and the bit-line capping layer include hydrogen, and
a hydrogen concentration of the cell etch stop layer is different from a hydrogen concentration of the bit-line dielectric layer and a hydrogen concentration of the bit-line capping layer.

3. The semiconductor device of claim 1, wherein
the peripheral gate structure further includes a gate sidewall capping structure in contact with a sidewall of the peripheral gate capping layer, and
the gate sidewall capping structure is between the sidewall of the peripheral gate capping layer and the peripheral etch stop layer.

4. The semiconductor device of claim 3, further comprising a dielectric structure between the cell region and the peripheral region,
wherein an upper portion of the gate sidewall capping structure is in contact with the sidewall of the peripheral gate capping layer,
wherein a lower portion of the gate sidewall capping structure is in contact with a top surface of the dielectric structure, and
wherein a width of the upper portion of the gate sidewall capping structure is less than a width of the lower portion of the gate sidewall capping structure.

5. The semiconductor device of claim 1, wherein
the substrate further includes a dummy region between the cell region and the peripheral region,
the semiconductor device further comprises a dummy line structure that overlaps the dummy region, and
the peripheral etch stop layer covers the dummy line structure.

6. The semiconductor device of claim 5, wherein
the dummy line structure includes a dummy line conductive layer and a dummy line capping layer on the dummy line conductive layer,
the dummy line capping layer and the peripheral etch stop layer include hydrogen, and
a hydrogen concentration of the peripheral etch stop layer is different from a hydrogen concentration of the dummy line capping layer.

7. The semiconductor device of claim 5, wherein
the dummy line structure further includes a dummy line sidewall capping structure in contact with a sidewall of the dummy line capping layer, and
the dummy line sidewall capping structure is between the sidewall of the dummy line capping layer and the peripheral etch stop layer.

8. The semiconductor device of claim 1, wherein
the peripheral etch stop layer includes a contact surface in contact with a bottom surface of the cover dielectric layer, and
the contact surface of the peripheral etch stop layer is at a level the same as a level of a top surface of the cell etch stop layer.

9. The semiconductor device of claim 1, wherein
the peripheral gate capping layer, the peripheral etch stop layer, and the cover dielectric layer include carbon, and
a carbon concentration of the peripheral etch stop layer is different from a carbon concentration of the peripheral gate capping layer and a carbon concentration of the cover dielectric layer.

10. A semiconductor device, comprising:
a substrate that includes a cell region and a peripheral region, wherein the cell region includes a cell active pattern;
a cell gate structure on the cell active pattern;
a bit-line structure electrically connected to the cell active pattern;
a peripheral gate structure on the peripheral region;
a peripheral etch stop layer on the peripheral gate structure; and
a cover dielectric layer on the peripheral etch stop layer,
wherein the bit-line structure includes:
a bit-line conductive layer;
a bit-line dielectric layer on the bit-line conductive layer;
a cell etch stop layer on the bit-line dielectric layer; and
a bit-line capping layer on the cell etch stop layer,
wherein the peripheral gate structure includes:
a peripheral gate conductive layer;
a peripheral gate capping layer on the peripheral gate conductive layer; and
a gate sidewall capping structure in contact with the peripheral etch stop layer and a sidewall of the peripheral gate conductive layer,
wherein the gate sidewall capping structure includes nitride.

11. The semiconductor device of claim 10, wherein the gate sidewall capping structure does not include oxide.

12. The semiconductor device of claim 10, further comprising a dielectric structure between the cell region and the peripheral region,
wherein the peripheral etch stop layer is in contact with a top surface of the dielectric structure.

13. The semiconductor device of claim 10,
wherein the peripheral etch stop layer is in contact with a top surface of the peripheral gate capping layer.

14. The semiconductor device of claim 10, wherein the cover dielectric layer is in contact with a top surface of the peripheral gate capping layer.

15. The semiconductor device of claim 10, wherein
the peripheral region includes a peripheral active pattern,
the peripheral gate structure is on the peripheral active pattern, and
the peripheral active pattern includes a lattice defect pattern.

16. The semiconductor device of claim 15, wherein
the peripheral active pattern includes a first part and a second part on opposite sides of the lattice defect pattern, and
a lattice of the first part of the peripheral active pattern is in disagreement with a lattice of the second part of the peripheral active pattern.

17. The semiconductor device of claim 10, wherein
the peripheral etch stop layer includes carbon, and
a carbon concentration of the peripheral etch stop layer is different from a carbon concentration of the gate sidewall capping structure.

18. A semiconductor device, comprising:
a substrate that includes a cell region, a dummy region, and a peripheral region, wherein the cell region includes a cell active pattern;
a cell gate structure on the cell active pattern;
a dielectric structure on the dummy region and the peripheral region;
a bit-line structure electrically connected to the cell active pattern;
a dummy line structure that overlaps the dummy region;
a peripheral gate structure on the peripheral region;
a node contact on the cell active pattern;
a landing pad on the node contact;
a peripheral etch stop layer on the peripheral gate structure; and
a cover dielectric layer on the peripheral etch stop layer,
wherein the bit-line structure includes:
a bit-line conductive layer;
a bit-line dielectric layer on the bit-line conductive layer;
and
a bit-line capping layer on the bit-line dielectric layer,
wherein the dummy line structure includes:
a dummy line conductive layer; and
a dummy line capping layer on the dummy line conductive layer,
wherein the peripheral gate structure includes:
a peripheral gate conductive layer; and
a peripheral gate capping layer on the peripheral gate conductive layer,
wherein the peripheral etch stop layer is in contact the dummy line capping layer and the peripheral gate capping layer,
wherein the peripheral etch stop layer, the dummy line capping layer, and the peripheral gate capping layer include hydrogen and carbon,
wherein a hydrogen concentration of the peripheral etch stop layer is different from a hydrogen concentration of the dummy line capping layer and a hydrogen concentration of the peripheral gate capping layer, and
wherein a carbon concentration of the peripheral etch stop layer is different from a carbon concentration of the dummy line capping layer and a carbon concentration of the peripheral gate capping layer.

19. The semiconductor device of claim 18, wherein
the peripheral gate structure further includes a gate sidewall capping structure in contact with a sidewall of the peripheral gate conductive layer, and
the gate sidewall capping structure includes nitride.

20. The semiconductor device of claim 19, wherein the peripheral etch stop layer is in contact with the gate sidewall capping structure.
